(19) United States
(12) Patent Application Publication
(10) Pub. No.: US 2009/0219750 A1
(43) Pub. Date: Sep. 3, 2009

(54) NONVOLATILE MEMORY DEVICE AND METHOD OF CONTROLLING THE SAME

(75) Inventors: Naoya TOKIWA, Fujisawa-shi (JP); Hiroshi Maejima, Chigasaki-shi (JP); Hideo Mukai, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/394,487

(22) Filed: Feb. 27, 2009

(30) Foreign Application Priority Data
Feb. 29, 2008 (JP) 2008-050710

(51) Int. Cl. G11C 11/00; G11C 7/00; G11C 8/00

(52) U.S. Cl. 365/148; 365/189.011; 365/230.01

(57) ABSTRACT

A nonvolatile memory device comprises a memory cell array including first and second mutually crossing lines and electrically erasable programmable memory cells arranged at intersections of the first and second lines, each memory cell containing a variable resistive element; a line selector circuit operative to decode an address signal to select the first and second lines; and a control circuit operative to execute control on at least one of data erase, write and read for the memory cell connected between the first and second lines selected at the line selector circuit. The control circuit executes control based on one parameter selected among a plurality of parameters. The line selector circuit specifies the parameter based on a first address portion in the address signal and selects the first and second lines based on a second address portion in the address signal.

### CROSS-REFERENCE TO RELATED APPLICATION

This application is based upon and claims the benefit of priority from prior Japanese Patent Application No. 2008-50710, filed on Feb. 29, 2008, the entire contents of which are incorporated herein by reference.

### BACKGROUND OF THE INVENTION

1. Field of the Invention

The present invention relates to a nonvolatile memory device comprising electrically erasable programmable nonvolatile memory cells, and a method of controlling the same. In particular, it relates to a nonvolatile memory device using as a memory element a variable resistive element of which resistance is stored as data, and a method of controlling the same.

2. Description of the Related Art

Nonvolatile memory devices include an electrically erasable programmable memory device operative to nonvolatilely store information on the resistance of a variable resistive element as known. Examples of the memory device of such the type include: a PCRAM (Phase-Change Random Access Memory) that uses a chalcogenide element as the variable resistive element; a ReRAM (Resistive Random Access Memory) that uses a transition metal oxide element; and a CBRAM that changes the resistance by precipitating metal cations to form a bridge (contacting bridge) between electrodes and ionizing the precipitated metal to destruct the bridge as known.

A high-density and low-cost production prefers an arrangement of memory elements at cross-points of column selection lines and row selection lines orthogonal thereto while operational easiness desires a resistive memory that includes a diode element arranged in series with the variable resistive element (Y. Hosoi et al., “High Speed Unipolar Switching Resistance RAM (RRAM) Technology”, IEEE International Electron Devices Meeting 2006 Technical Digest pp. 793-796). A higher density can be achieved with a three-dimensional arrangement of memory cells desirably (JP 2005-522045A).

### SUMMARY OF THE INVENTION

In an aspect the present invention provides a nonvolatile memory device, comprising: a memory cell array including first and second mutually crossing lines and electrically erasable programmable memory cells arranged at intersections of the first and second lines, each memory cell containing a variable resistive element nonvolatilely storing a resistance of the variable resistive element as data; a line selector circuit operative to decode an address signal to select the first and second lines; and a control circuit operative to execute control on at least one of data erase, write and read for the memory cell connected between the first and second lines selected by the line selector circuit, wherein the control circuit executes control based on one parameter selected among a plurality of parameters, the line selector circuit specifies the parameter based on a first address portion in the address signal and selects the first and second lines based on a second address portion in the address signal.

In another aspect the present invention provides a nonvolatile memory device, comprising: a memory cell array including first and second mutually crossing lines and electrically erasable programmable memory cells arranged at intersections of the first and second lines, each memory cell containing a variable resistive element nonvolatilely storing a resistance of the variable resistive element as data; a line selector circuit operative to decode an address signal to select the first and second lines; and a control circuit operative to execute control on at least one of data erase, write and read for the memory cell connected between the first and second lines selected at the line selector circuit, wherein the line selector circuit executes selection of the first line and the second line based on the address signal time-divided into two or more.

In an aspect the present invention provides a method of controlling a nonvolatile memory device, the device comprising a memory cell array including first and second mutually crossing lines and electrically erasable programmable memory cells arranged at intersections of the first and second lines, each memory cell containing a variable resistive element nonvolatilely storing a resistance of the variable resistive element as data, a line selector circuit operative to decode an address signal to select the first and second lines, and a control circuit operative to execute control on at least one of data erase, write and read for a memory cell connected between the first and second lines selected at the line selector circuit, the method comprising: specifying the parameter based on a first address portion in the address signal at the line selector circuit; selecting the first and second lines based on a second address portion in the address signal at the line selector circuit; and executing control at the control circuit based on one parameter specified among a plurality of parameters at the line selector circuit.

### BRIEF DESCRIPTION OF THE DRAWINGS

FIG. 1 is a block diagram of a nonvolatile memory device according to a first embodiment of the present invention.

FIG. 2 is a circuit diagram showing an equivalent circuit of a memory cell array in the same memory device.

FIG. 3 is a perspective view of the same memory cell array.

FIG. 4 is a cross-sectional view of a memory cell in the same memory cell array.

FIG. 5 provides a schematic cross-sectional view of a variable resistive element in a ReRAM cell in the same memory cell array and the operational principle thereof.

FIG. 6 provides schematic cross-sectional views of a non-ohmic element in the same memory cell array.

FIG. 7 shows a three-dimensional layout of a contact portion at a word line end in the same memory cell array.

FIG. 8 shows resistance distributions and a definition of the states in the same memory cell.

FIG. 9 shows voltage-time relations among write (set), erase (reset) and read for the same memory cell.

FIG. 10 schematically shows a parasitic resistance on a contact portion at a word line end in the same memory cell.

FIG. 11 shows waveforms on data reading operation in ReRAM according to the same embodiment.

FIG. 12 shows waveforms on data reading operation in ReRAM according to a modification of the same embodiment.

FIG. 13 is a block diagram showing a means for changing the voltage setting per layer in ReRAM of the same embodiment.

FIG. 14 shows waveforms on reading operation outside and inside the device in ReRAM according to the same embodiment.

FIG. 15 shows waveforms on reading operation outside and inside a device according to a second embodiment of the present invention.

FIG. 16 shows waveforms on reading operation outside and inside a device according to a third embodiment of the present invention.

FIG. 17 is a block diagram of a nonvolatile memory device according to a fourth embodiment of the present invention.

FIG. 18 shows waveforms on reading operation outside and inside a device according to a fifth embodiment of the present invention.

FIG. 19 shows waveforms on reading operation outside and inside the device according to the fifth embodiment of the present invention.

### DETAILED DESCRIPTION OF THE EMBODIMENTS

The embodiments of the present invention will now be described with reference to the drawings.

### First Embodiment

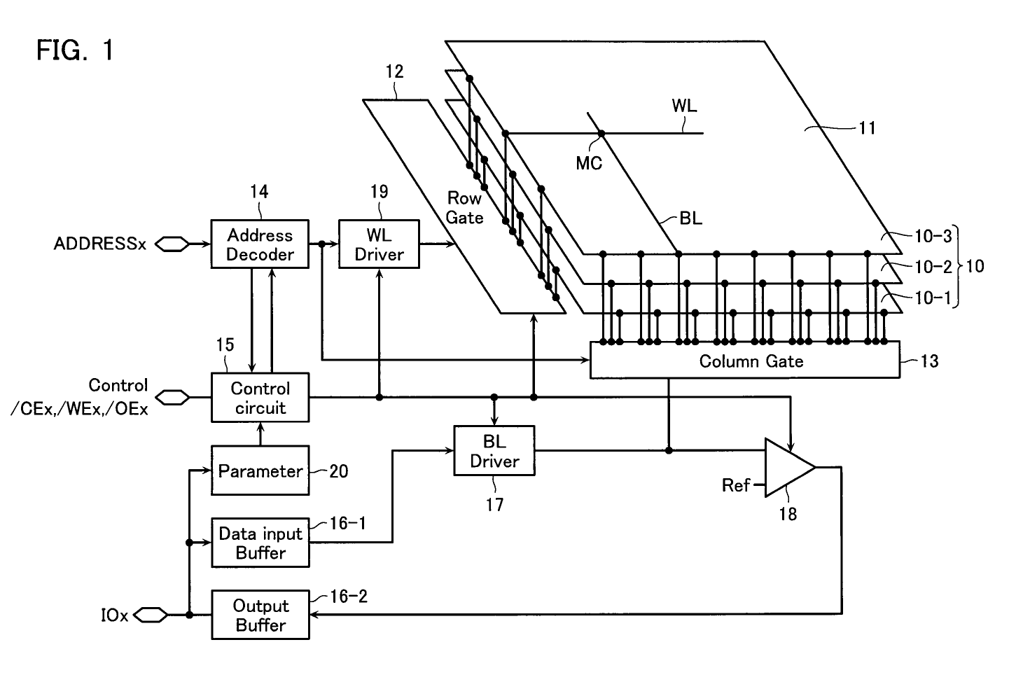

FIG. 1 shows the entire configuration of a nonvolatile memory device according to a first embodiment of the present invention.

The nonvolatile memory device comprises a memory block 10, which includes MATs 10-1, 10-2, 10-3 stacked on a semiconductor substrate to form a plurality of memory layers. Furthermore, a plurality of memory blocks may be arranged two-dimensionally. Formed on each MAT 10-1, 10-2, 10-3 is a memory cell array 11, which includes a plurality of word lines WL arranged in parallel, a plurality of bit lines BL arranged in parallel and orthogonal thereto, and memory cells MC arranged at intersections of the word lines WL and the bit lines BL, which use a variable resistive element, as in a PCRAM (Phase-Change RAM), a ReRAM (Resistive RAM) or the like. On a portion of the semiconductor substrate connected to one end of the word lines WL of the memory block 10, a row gate 12 is provided to drive and voltage-control the word lines WL in the memory cell array in accordance with an input address. On another portion of the semiconductor substrate connected to one end of the bit lines BL of the memory block 10, a column gate 13 is provided to switch between a selected bit line BL and non-selected bit lines BL in accordance with the input address.

An address signal input from external is fed to an address decoder 14. The address decoder 14 is included in a line selector circuit together with the row gate 12 and the column gate 13. It interprets the address signal input, creates a layer address from a first address portion in the address signal, and creates a column address and a row address from a second address portion in the address signal. The layer address is given to a control circuit 15, the row address to the row gate 12 via a word line driver 19, and the column address to the column gate 13. The control circuit 15 receives control signals for controlling the device (such as a chip enable signal/CEx, a write enable signal/WEx, an output enable signal/OEx or the like) given from a host device outside the device, and controls the device.

Write data given from outside the device is held in a data input buffer 16-1 and supplied to a bit line driver 17. The bit line driver 17 supplies the column gate 13 with voltages required for write (set), erase (reset) and read based on the input data. The potential on the selected bit line BL selected by the column gate 13 is compared with a reference potential Ref at a sense amplifier circuit 18, whose output is provided as read-out data via an output buffer 16-2 to external. The word line driver 19 supplies the selected word line WL selected by the row gate 12 with word-line driver voltages required for write (set), erase (reset) and read, which have the magnitudes set at the control circuit 15. A parameter circuit 20 is configured to hold parameters required at the control circuit 15 for control of data write, erase and read and adjust the parameter, if required, according to external operation.

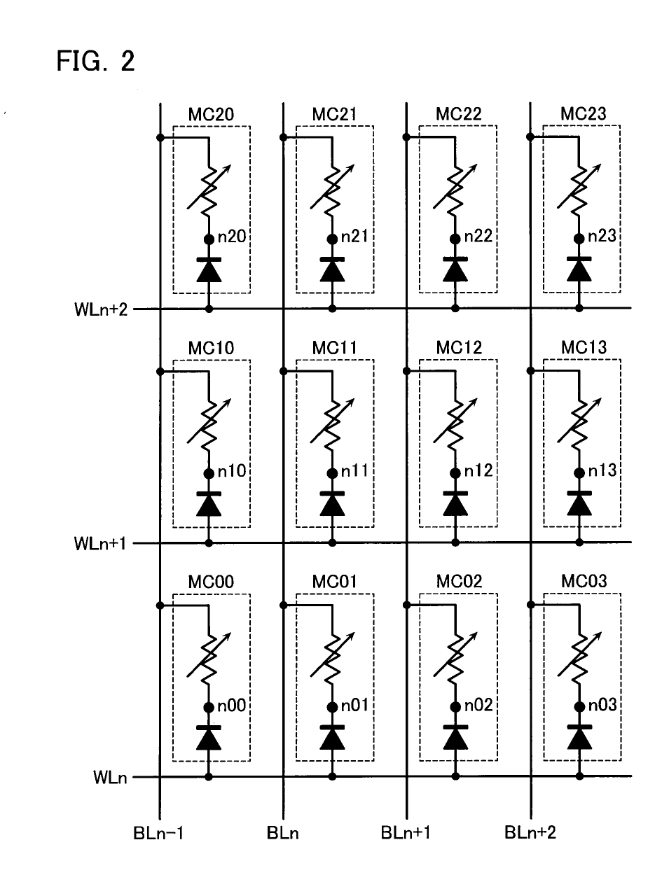

FIG. 2 shows a configuration of the memory cell array 11 in the nonvolatile memory device. For simplicity of description, the memory cell array 11 only shows a range including memory cells MC arranged three in the column direction and four in the row direction. Word lines WLn to WLn+2 are arranged in the row direction and bit lines BLn−1 to BLn+2 in the column direction such that they cross at right angles. Arranged at intersections thereof are nonvolatile memory cells MC00-MC23, each including a variable resistive element and a diode element. The diode element shown in this example has an anode connected to the word line and a cathode connected to the bit line side. The variable resistive element is connected between the cathode of the diode and the bit line in the shown form. However, the connection is not limited to that form.

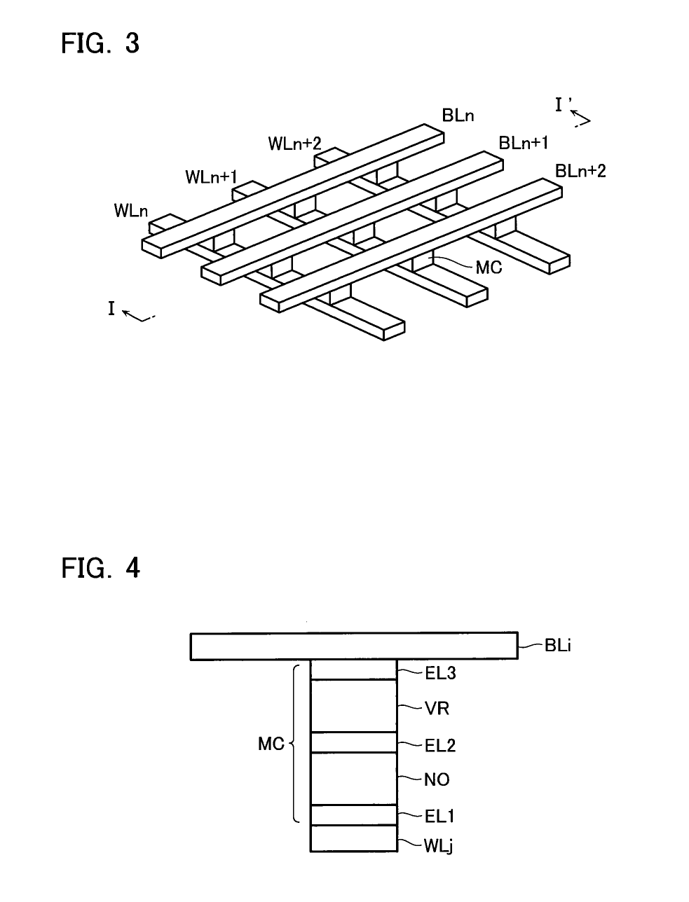

FIG. 3 is a perspective view of part of the memory cell array 11 on one MAT. FIG. 4 is a cross-sectional view of one memory cell taken along I-I′ line and seen from the direction of the arrow in FIG. 3. In the present embodiment, the bit lines BL and the word lines WL are independently arranged on a layer basis. Alternatively, the bit line BL and the word line WL may be configured such that at least one of them is shared by the upper and lower layers.

The memory cells MC are vertically sandwiched between the bit lines BLn, BLn+1, . . . and the word lines WLn, WLn+1, . . . and thus have a vertically stacked structure. Desirably, the bit lines BLn, BLn+1, . . . and the word lines WLn, WLn+1, . . . are composed of heat-resistive low-resistance material such as W, WSi, NiSi, CoSi or the like.

The memory cell MC comprises a serial connection circuit of a variable resistive element VR and a non-ohmic element NO as shown in FIG. 4.

The variable resistive element VR can vary the resistance through current, heat, or chemical energy on voltage application. Arranged on an upper and a lower surface thereof are electrodes EL2, EL3 serving as a barrier metal layer and an adhesive layer. Material of the electrodes may include Pt, Au, Ag, TiAlN, SrRuO, Ru, RuN, Ir, Co, Ti, TiN, TaN, LaNiO, Al, PtIrOx, PtRhOx, Rh/TaAlN or the like. A metal film capable of achieving uniform orientation may also be interposed. A buffer layer, a barrier metal layer and an adhesive layer may further be interposed.

Available examples of the variable resistive element VR include: one that changes the resistance in accordance with a phase change between the crystalline state and the amorphous state, such as a chalcogenide (PCRAM); one that changes the resistance by precipitating metal cations to form a bridge (contacting bridge) between electrodes and ionizing the precipitated metal to destruct the bridge (CBRAM); and one that changes the resistance by applying a voltage or current (ReRAM) (which is roughly divided into one that causes a variation in resistance in accordance with the presence/absence of charge trapped in charge traps present in the electrode interface, and one that causes a variation in resistance in accordance with the presence/absence of the conduction path due to an oxygen loss and so forth).

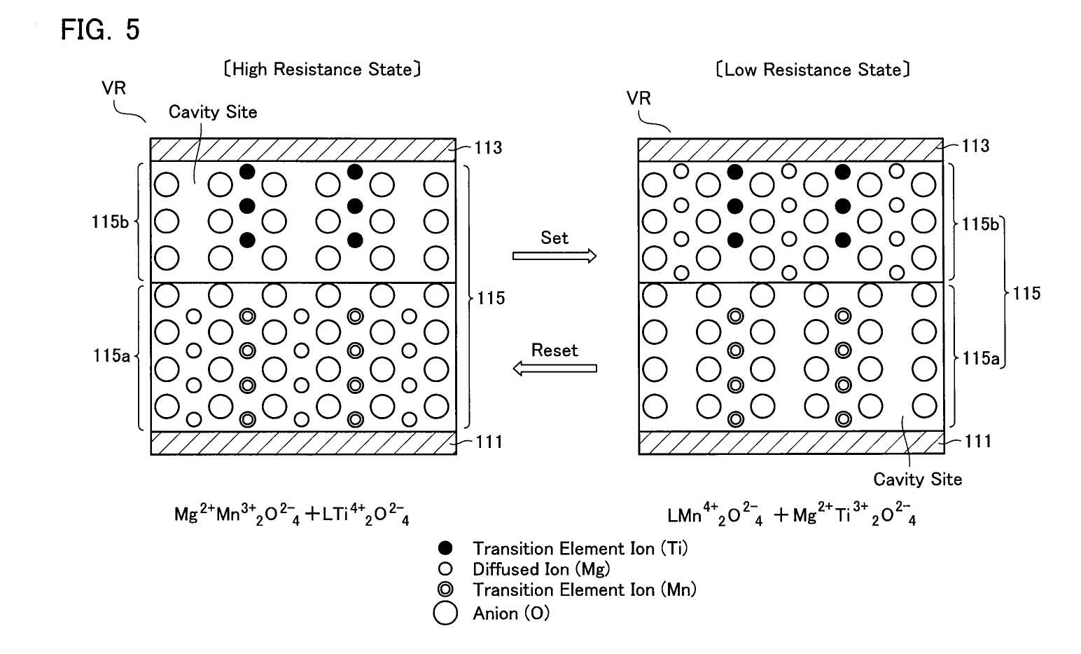

FIG. 5 shows an example of the ReRAM. The variable resistive element VR shown in FIG. 5 includes a recording layer 115 arranged between electrode layers 111 and 113. The recording layer 115 is composed of a composite compound containing at least two types of cation elements. At least one of the cation elements is a transition element having the d-orbit incompletely filled with electrons, and the shortest distance between adjacent cation elements is 0.32 nm or lower. Specifically, it is represented by a chemical formula AₓM_{y}X_{z} (A and M are different elements) and may be formed of material having a crystal structure such as a spinel structure (AM₂O₄), an ilmenite structure (AMO₃), a delafossite structure (AMO₂), a LiMoN₂ structure (AMN₂), a wolframite structure (AMO₄), an olivine structure (A₂MO₄), a hollandite structure (AₓMO₂), a ramsdellite structure (AₓMO₂), a perovskite structure (AMO₃) or the like.

In the example of FIG. 5, the recording layer 115 sandwiched between the electrode layers 111 and 113 is formed of two layers: a first compound layer 115a and a second compound layer 115b. The first compound layer 115a is arranged on the side close to the electrode layer 111 and represented by a chemical formula AₓM1_{y}X1_{z}. The second compound layer 115b is arranged on the side close to the electrode layer 113 and has cavity sites capable of accommodating cation elements from the first compound layer 115a.

In the example of FIG. 5, A represents Mg, M1 represents Mn, and X1 represents O in the first compound layer 115a. The second compound layer 115b contains Ti shown with black circles as transition element ions. In the first compound layer 115a, a small white circle represents a diffused ion (Mg), a large white circle represents an anion (O), and a double circle represents a transition element ion (Mn). The first compound layer 115a and the second compound layer 115b may be stacked in multiple layers such as two or more layers.

In such the variable resistive element VR, potentials are given to the electrode layers 111, 113 so that the first compound layer 115a serves as an anode and the second compound layer 115b serves as a cathode to cause a potential gradient in the recording layer 115. In this case, part of diffused ions in the first compound layer 115a migrate through the crystal and enter the second compound layer 115b on the cathode side. The crystal of the second compound layer 115b includes cavity sites capable of accommodating diffused ions. Accordingly, the diffused ions moved from the first compound layer 115a are trapped in the cavity sites. Therefore, the valence of the transition element ion in the first compound layer 115a increases while the valence of the transition element ion in the second compound layer 115b decreases. In the initial state, the first and second compound layers 115a, 115b may be in the high-resistance state. In such the case, migration of part of diffused ions in the first compound layer 115a therefrom into the second compound layer 115b generates conduction carriers in the crystals of the first and second compounds, and thus both have electric conduction. The programmed state (low-resistance state) may be reset to the erased state (high-resistance state) by supplying a large current flow in the recording layer 115 for sufficient time for Joule heating to facilitate the oxidation reduction reaction in the recording layer 115. Application of an electric field in the opposite direction from that at the time of setting may also allow reset.

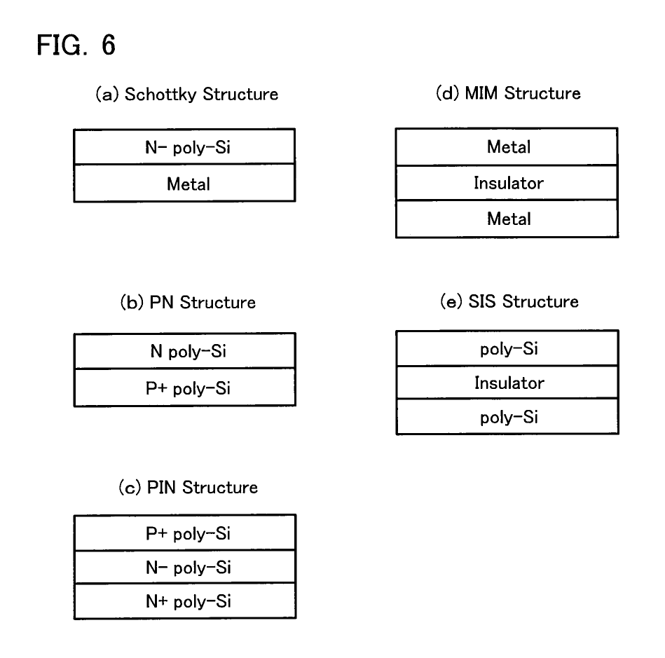

The non-ohmic element NO may include various diodes as shown in FIG. 6, for example, (a) a Schottky diode, (b) a PN-junction diode, (c) a PIN diode and may have (d) a MIM (Metal-Insulator-Metal) structure, and (e) a SIS (Silicon-Insulator-Silicon) structure. In this case, electrodes EL1, EL2 forming a barrier metal layer and an adhesive layer may be interposed. If a diode is used, from the property thereof, it can perform the unipolar operation. In the case of the MIM structure or SIS structure, it can perform the bipolar operation. The non-ohmic element NO and the variable resistive element VR may be arranged in the opposite direction compared with FIG. 4 and the polarity of the non-ohmic element NO may be inverted.

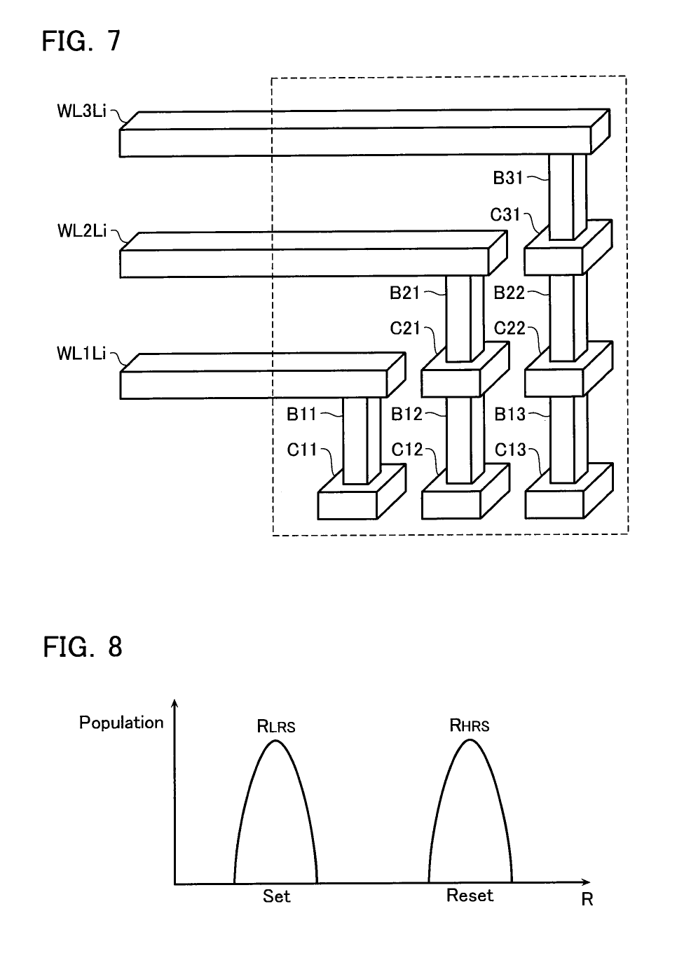

FIG. 7 shows a word line terminal, for example, in the memory block 10 of FIG. 1. A word line WL1Li in a first layer is connected to a silicon substrate in a zero-th layer through a via-hole B11 and a contact C11. A word line WL2Li in a second layer is connected to the silicon substrate through a via-hole B21, a contact C21, a via-hole B12 and a contact C12. A word line WL3Li in a third layer is connected to the silicon substrate through a via-hole B31, a contact C31, a via-hole B22, a contact C22, a via-hole B13 and a contact C13.

In the case of the present embodiment, as shown in FIG. 8, the memory cell MC stores binary data using a high-resistance state (HRS) as the erased state (for example, data “1”) and a low-resistance state (LRS) as the programmed state (for example, data “0”). In this case, “0” writing to turn a cell in the high-resistance state (HRS) to the low-resistance state (LRS) is defined as writing in a narrow sense (or setting), and “1” writing to turn a cell in the low-resistance state (LRS) to the high-resistance state (HRS) as erasing (or resetting). FIG. 8 shows an example of such the resistance distributions.

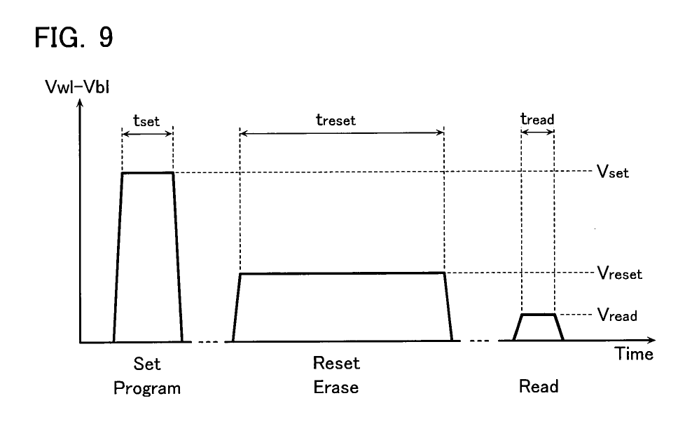

FIG. 9 shows voltage pulses applied between the word line WL and the bit line BL on data write, erase and read. The “0” writing (or setting) to turn a cell in the high-resistance state (HRS) to the low-resistance state (LRS) can be achieved by determining the voltage difference across the memory cell between the word line and the bit line at Vₛₑₜ in FIG. 9, which is applied for a period of time tₛₑₜ. The “1” writing to turn a cell in the low-resistance state (LRS) to the high-resistance state (HRS) can be achieved by determining the voltage difference across the memory cell MC between the word line WL and the bit line BL at Vᵣₑₛₑₜ, which is applied for a period of time tᵣₑₛₑₜ. In this case, relations between tᵣₑₛₑₜ>tₛₑₜ and between Vₛₑₜ>Vᵣₑₛₑₜ are retained. Reading data from the memory cell MC can be achieved by placing a voltage difference with a voltage V_{read} and time t_{read} between the word line WL and the bit line BL, different from set and reset.

The following example of specific reading is used to show the problem to be solved in the invention and describe specific embodiments to solve the problem.

As described above, in the ReRAM, a voltage difference with a short pulse width (for example, several tens of nanoseconds) is applied for reading. In this case, the voltage difference is applied such that the diode element connected between the selected word line and the bit line is forward-biased and feeds a current required for read, thereby sensing the magnitude of the cell current in accordance with the resistance of the resistive element to decide the stored state.

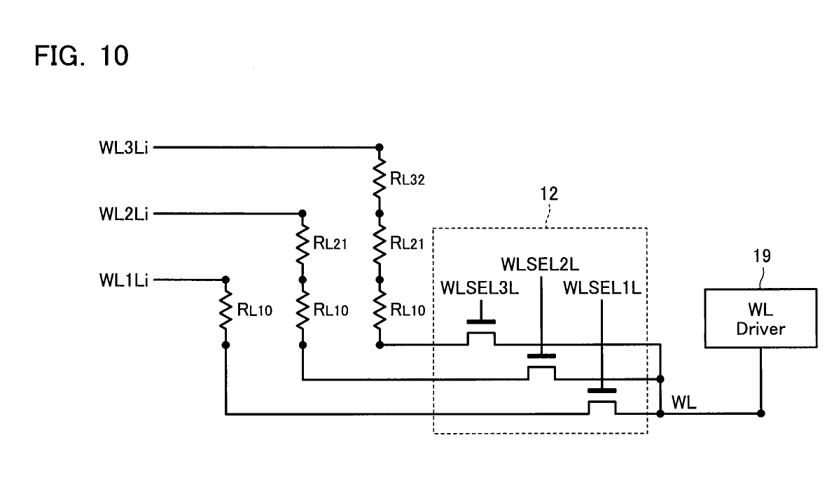

FIG. 10 shows an equivalent circuit of the word lines in the layers shown in FIG. 7 and the row gate 12 operative to select them. There is a contact resistance component RL10 from the word line driver 19 to one end of the word line WL1Li on reading in the first layer. There is a contact resistance component RL10+RL21 on reading in the second layer and RL10+RL21+RL32 on reading in the third layer. In sensing the resistance state of the memory cell MC with current, the voltage effectively applied across the electrodes of the memory cell MC is obtained by subtracting the IR drop resulted from these resistances. Therefore, the value of the effective voltage on reading in the first layer differs from that on reading in the third layer as a problem.

In addition, the parasitic capacity on the contact portion causes a difference in bit-line voltage amplitude as an inherent problem.

With this regard, the present embodiment controls the output voltage from the word line driver 19 by previously adding the contact resistance component, thereby equates the effective applied voltage viewed as the voltage difference across the memory cell MC even on reading among different layers.

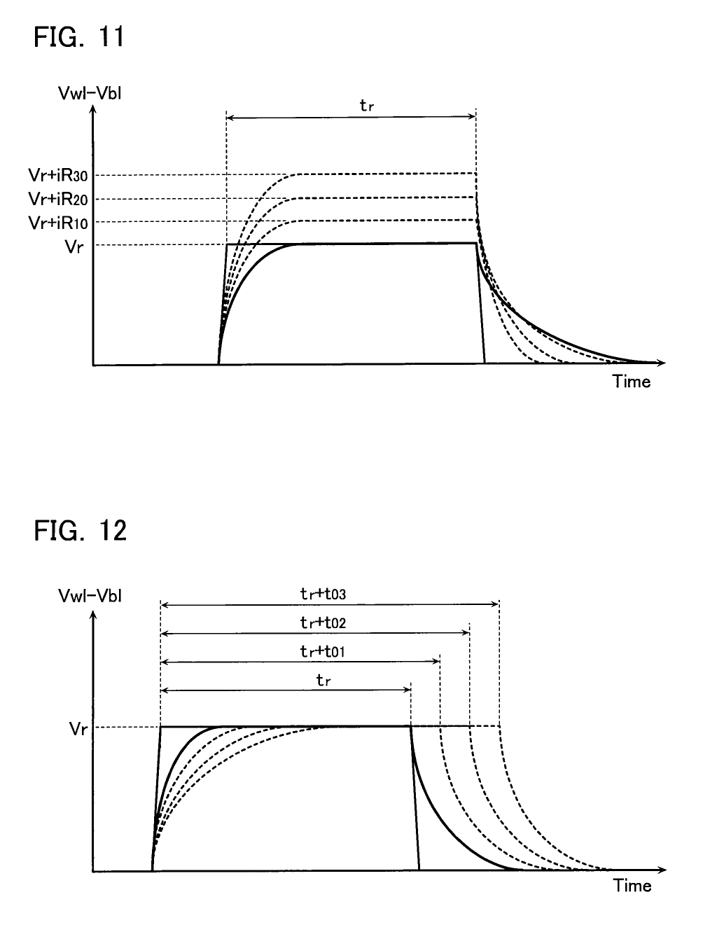

FIG. 11 shows a read voltage pulse. When the voltage difference applied across the memory cell MC is Vr, a cell current, i, causes a voltage drop, i*R10 (R10=RL10), on reading in the first layer. Accordingly, the output voltage from the word line driver 19 is provided as Vr+i*R10. There is a voltage drop, i*R20 (R20=RL10+RL21), on reading in the second layer. Accordingly, the output voltage from the word line driver 19 is set at Vr+i*R20. There is a voltage drop, i*R30 (R30=RL10+RL21+RL32), on reading in the third layer. Accordingly, the output voltage from the word line driver 19 is set at Vr+i*R30. The output voltage from the word line driver 19 may previously be changed by anticipating these voltage drops may also contain the voltage drop by the contact resistance present on the bit line BL, not shown, and the line resistance of the bit line BL itself.

According to the present embodiment, the voltage difference applied across the memory cell MC can be made closer to Vr effectively. Even in reading from memory cells in different layers, contact resistance-compensated reading can be executed and potential environments imparted on reading among layers can be set even.

Another embodiment includes an effective form that changes the time for applying a potential required for reading if there is a margin of time in reading out to outside the device.

Specifically, as shown in FIG. 12, when a pulse application time required for reading in an ideal state containing no contact resistance component is tᵣ, the pulse application time required for reading is set at tᵣ+tᵣ₀₁ in the first layer, tᵣ+tᵣ₀₂ in the second layer, and tᵣ+tᵣ₀₃ in the third layer. This variable pulse time may be configured to compensate for the parasitic capacity component, which is caused by the difference in the number of contacts also present on the bit line BL.

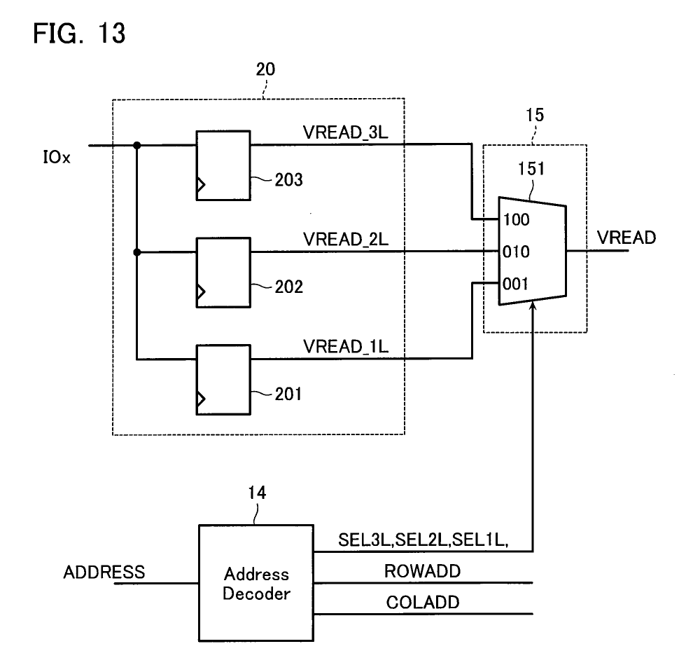

A means for changing the value of the output voltage from the word line driver 19 from layer to layer is shown in FIG. 13, which exemplifies selection among memory cells in three different layers.

The parameter circuit 20 includes three resistors 201, 202, 203 operative to store parameters VREAD_1L, VREAD_2L, VREAD_3L for determining the values of the word-line driver voltage corresponding to the respective layers. From these parameters, either is selected at a selector 151 in the control circuit 15 and supplied as a word-line driver voltage setting VREAD to the word line driver 19. The address decoder 14 decodes a first address portion, including higher bits, for example, in an address signal fed from external, and provides a signal indicating which memory layer is selected, that is, a signal SEL1L indicating the first layer is selected, a signal SEL2L indicating the second layer is selected, or a signal SEL3L indicating the third layer is selected. Based on these signals SEL1L-SEL3L, the selector 151 selects one parameter among three parameters. The address decoder 14 decodes a second address portion, including lower bits, for example, in the address signal, and creates a row address ROWADD and a column address COLADD for use in selection of the word line WL and the bit line BL, which are provided to the row gate 12 and the column gate 13.

The resistors 201-203 operative to store the above voltage values may be configured to change the values via an I/O pin IOx arranged outside the device for improvement in convenience.

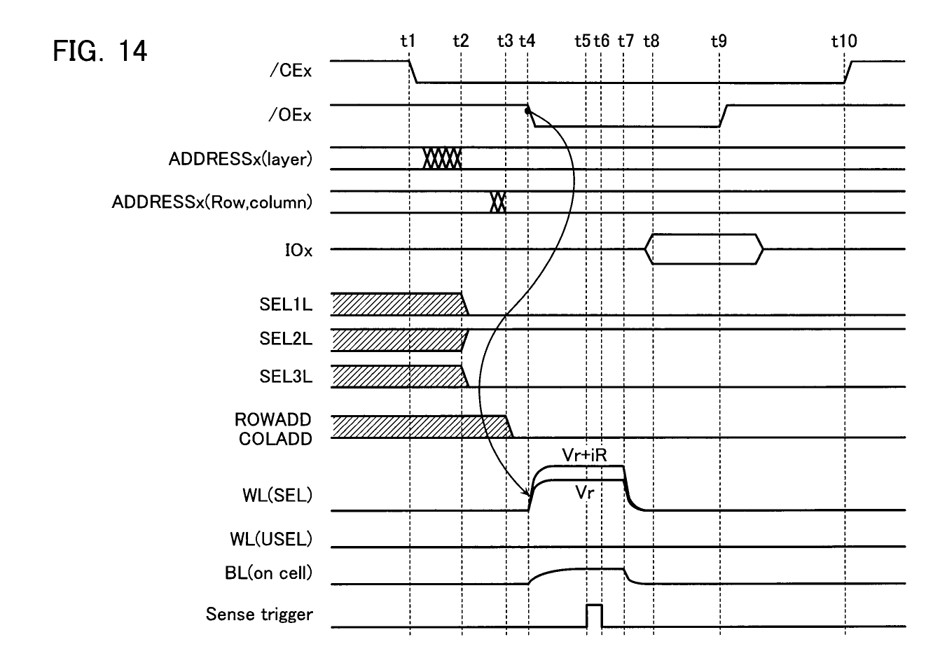

FIG. 14 shows timing waveforms of external control signals and internal control signals on data reading in the nonvolatile memory device according to the present embodiment.

When the chip enable signal/CEx fed from outside the device is made low-active at time t1, the device is activated and brought into the state to receive commands and control signals. In this state, an address signal is fed from external. The address signal includes a layer address in the first address portion and a row address and a column address in the second address portion. In the present embodiment, the layer address for layer selection is settled first at time t2. In accordance with the layer address, the signals for inner layer selection, SEL1L, SEL2L, SEL3L, are settled uniquely. As shown, SEL2L is selected. Thereafter, the column address and the row address in the same layer are settled at time t3 and then the output enable signal/OEx is changed from high level to low level at time t4. Thus, the start of reading can be instructed from outside the device. In response to this, the word line driver 19 starts application of the pulse to the selected word line for reading inside the device. At the same time, the word line driver 19 provides the voltage of which value is set with the parameter VREAD_2L selected in accordance with the layer address SEL2L settled by the time t2. The time t3 and the time t4 have an extremely short time difference (for example, around 5 nanoseconds). The timing between t3 and t8 corresponds to waveforms in FIG. 11.

The word line WL is biased to vary the potential on the bit line BL in accordance with the resistance of the memory cell MC. Therefore, during a period of time t5-t6, a sense trigger pulse is generated for sensing in the sense amplifier circuit 18. After completion of sensing, the word line WL is discharged at time t7 to finish sensing. The sensed data is transferred to the output buffer 16-2 and finally provided to external via the I/O pin IOx arranged on the device (time t8). The time t8 may be any time after the time t6 of completion of sensing and may locate before or after t7 arbitrarily.

For termination of reading, the output enable signal/OEx is changed to high level, thereby stopping the output from the I/O pin IOx at any time. Further, the chip enable signal/CEx may be changed to the standby state at time t10.

Usually, reading requires data output in a short time (for example, around 30 nanoseconds) and accordingly a fine potential dispersion after the starting time of charging the word line may possibly become one factor in deteriorating the reading speed.

Therefore, after the time t4, setting the voltage is required as stable as possible. With this regard, the voltage setting in accordance with the layer address shown in the present embodiment is required to be in the settled state at the time t4 of starting charging of the word line WL.

In the present embodiment, compared with the period of time after the timing t2 of settling the layer address until the timing t4 of changing the voltage setting on the read-targeted word line WL, set shorter to ensure the stable operation is the total time of: the interpretation of an address at the address decoder 14; the transmission delays of the signals SEL1L, SEL2L, SEL3L for selection of the settled layer; and the circuit delay in the selector 151 arranged in the control circuit 15 and the signal transmission delay of the selected word line driver voltage setting signal VREAD in the configuration of FIG. 13.

### Second Embodiment

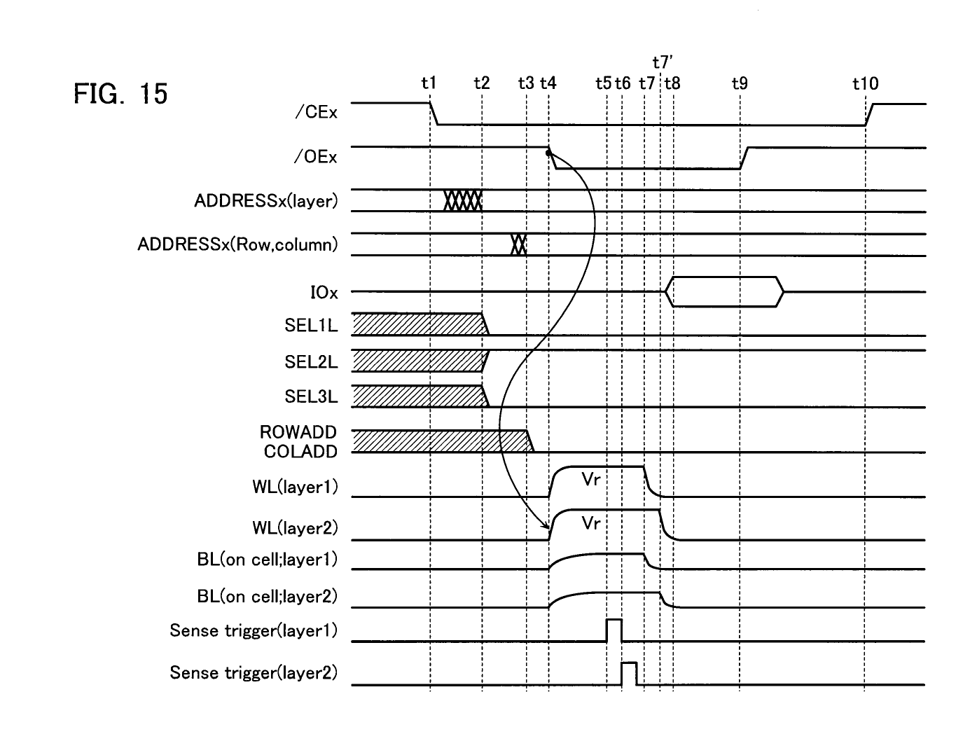

FIG. 15 is a timing waveform diagram on data reading in a nonvolatile memory device according to a second embodiment of the present invention.

While the output voltage from the word line driver is changed in the first embodiment, the timing including the sense trigger pulse is changed from layer to layer in the present embodiment. A parameter is settled at the time t2 of settling the layer and the control circuit 15 determines the output timing of the sense trigger pulse based on the settled parameter. In the shown example, the sense pulse is generated at the time t5 on selecting the first layer, and the sense trigger pulse is generated at the time t6 on selecting the second layer. The sense trigger pulse is usually originated from the time t4 of starting sensing and generated via plural delay circuits. Accordingly, it is essential that the layer selection signal has been settled by the time t4.

### Third Embodiment

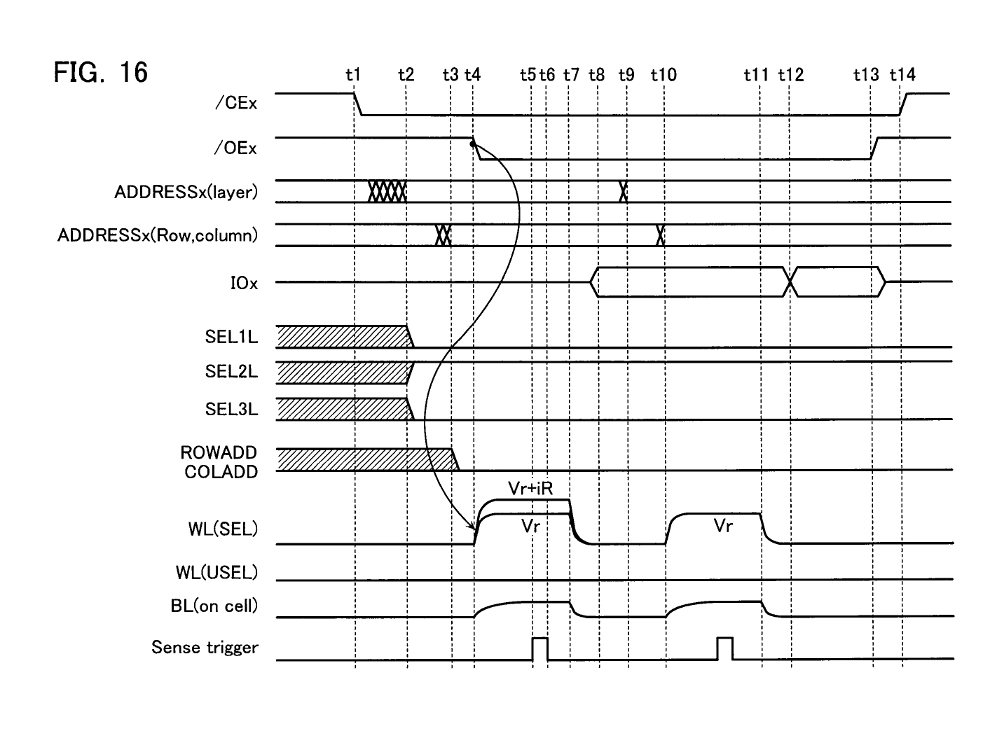

FIG. 16 is a timing waveform diagram on data reading in a nonvolatile memory device according to a third embodiment of the present invention.

This embodiment shows an example suitable for continuous reading while changing at least part of the address signal. In this embodiment, when the row address or the column address is changed at time t10, the device detects this and starts reading. Also in this case, it is required to settle the word line driver voltage setting signal VREAD at least by the time t10 of starting reading. Accordingly, the layer address is settled ahead at time t9 and the sum total of time after the layer address settlement until the signal transmission delay of the setting signal VREAD should be smaller than t10−t9.

### Fourth Embodiment

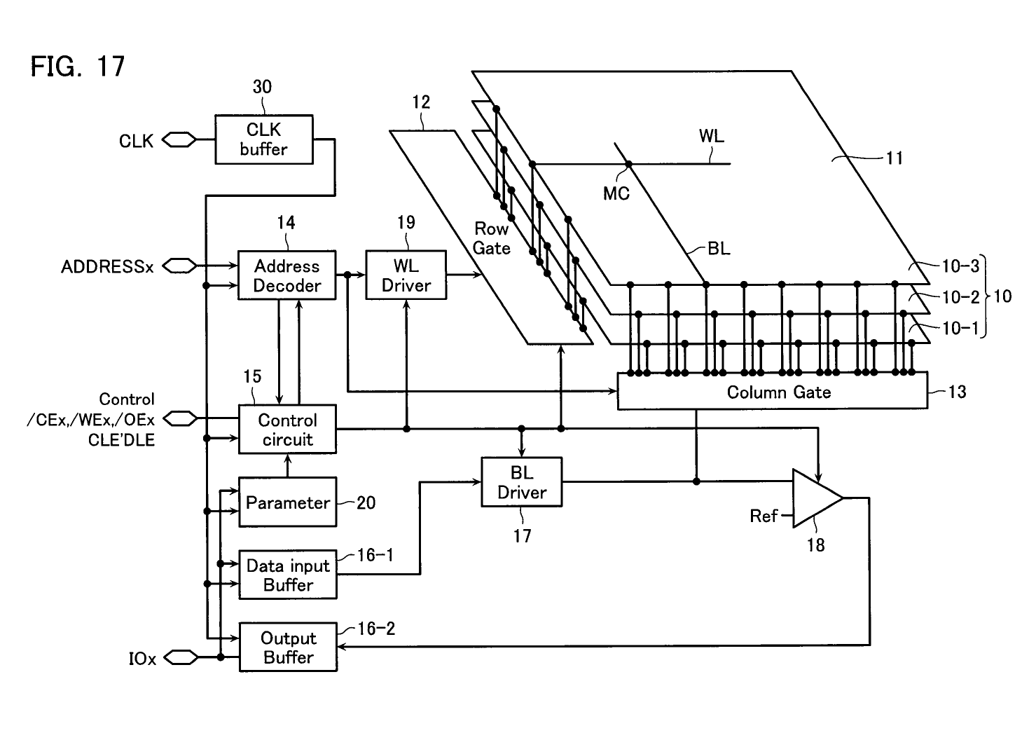

FIG. 17 is a block diagram showing the entire configuration of a nonvolatile memory device according to a fourth embodiment of the present invention.

The preceding embodiments are described on the assumption of operations for built-in instruments premised on asynchronous control using no clock signal in control or on control by microcomputers. If a large-scale control device-mounted internal common bus or memory-dedicated bus is used for access, though, control may be executed with a steadily supplied clock signal and a signal line in sync therewith.

The present embodiment includes a clock pin CLK provided to receive a clock signal at a certain period in at least 2 cycles from outside the device, and a clock buffer circuit 30 operative to receive the clock signal and execute waveform shaping and, if required, frequency dividing and multiplying. The output signal is fed to the address decoder 14, the control circuit 15, the parameter circuit 20, the input buffer 16-1 and the output buffer 16-2 and used to determine the control timing of the circuits.

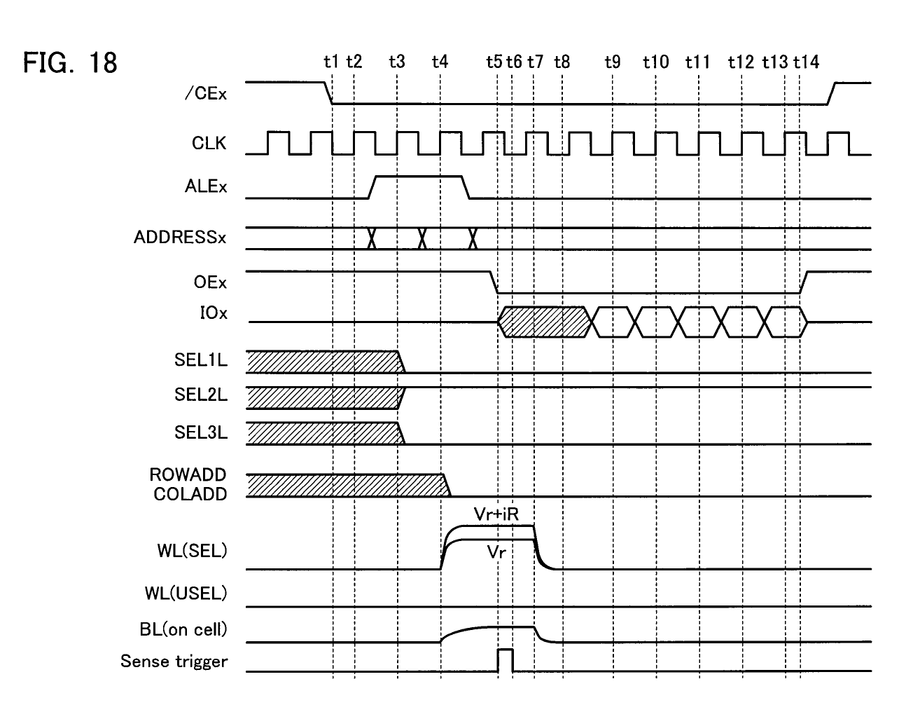

Timing waveforms of external control signals and internal control signals on data reading in the present embodiment are shown in FIG. 18 and described in detail.

The chip enable signal/CEx is used at time t1 to activate the device. The device may be configured such that it is activated in sync with a signal level transition in the clock signal (the transition point from low level to high level, that is, the positive edge in this example) at time t2.

At time t3, an address latch signal ALEx indicative of an address input is activated previously to take in the state of the address signal (first address input) and then, at time t4, similarly taken in (second address input). The first address input is configured to include a layer address and the second address input to include other addresses. At time t4, in accordance with the settled address, reading is started at the same time, followed by sensing (time t5) and so forth at certain timing. Then, after certain clock cycles, the data read out and fixed is provided to the I/O pin IOx. Thereafter, a burst reading for updating output data at a period in accordance with the clock cycles is allowed.

### Fifth Embodiment

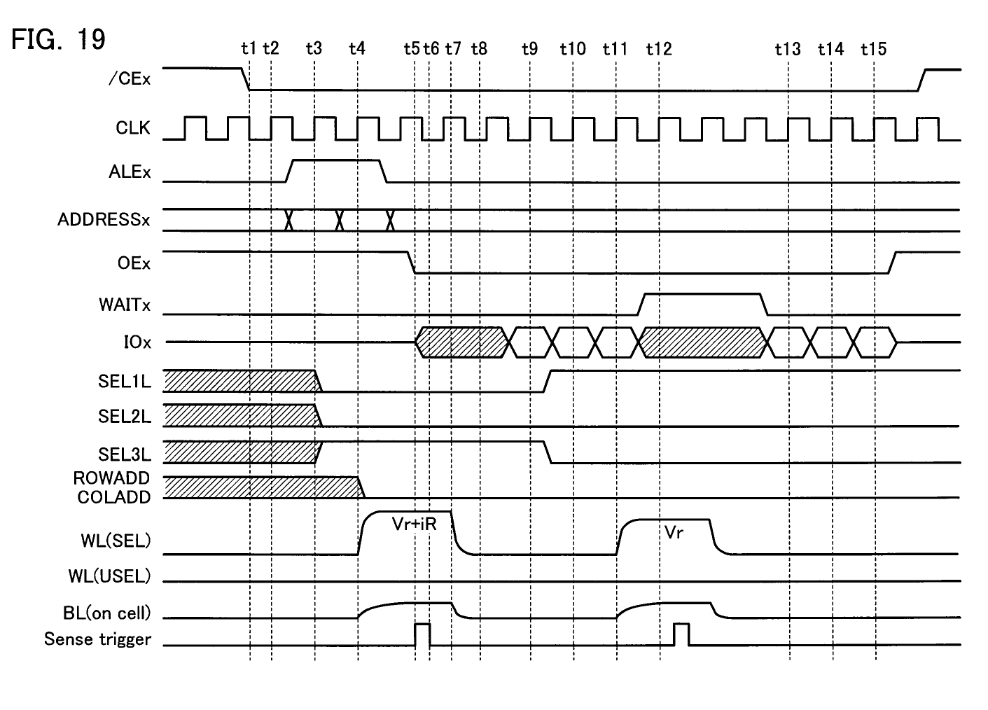

FIG. 19 relates to a modification of the fourth embodiment shown in FIG. 18 and shows a timing waveform diagram on continuous burst reading over different layers. The parts up to the time t9 are similar to those in FIG. 18. If an address counter, not shown, arranged in the internal address decoder 14 previously senses an occurrence of reading in a different layer inside the device after the time t9, the values of the layer address selection signals SEL1L, SEL2L, SEL3L are changed to provide for reading in the different layer. When a finite time elapsed after the settlement of the layer address, the device provides a word line driver output voltage in accordance with the layer address for reading from inside. Then certain clock cycles after completion of reading, continuous data output is executed in accordance with the clock signal periods (time t13-t15). In the case of data output over the layers, the data output may be stopped. If the data output is stopped, a signal WAITx indicative of the output stopped may be provided to outside the device.

In the fourth and fifth embodiments shown in FIGS. 18 and 19, with respect to a read address entering in sync with the clock, the address is supplied over at least 2 cycles or more. If the address is supplied in 2 cycles, the first address input includes at least a layer address for layer selection and the second address input includes other addresses. If a multi-cycle address is supplied, the layer address is settled prior to the final address input.

With such the configuration, read control in accordance with the layer address can be executed with stability, which allows the nonvolatile memory device to achieve improvement in reliability and high-speed operation.

The above embodiments are given the description on the control operation by the control circuit with examples of setting the word line potential for reading based on parameters, setting the word line voltage application time and setting the sensing timing. Though, the present invention is not limited to the above-described embodiments. For example, it is also applicable to setting other potentials with regard to memory cell reading. In addition, the control operation by the control circuit is not limited to reading but rather can be applied to setting various potentials and setting timings in writing (setting) and erasing (resetting) as well as other operations without departing from the scope and spirit of the present invention.

The parameters for access to the memory cell may be set not on a layer basis but on a two-dimensional area basis.

In the above embodiments, configuration that only one MAT is selected on read operation is described. However, this invention may be applicable to a configuration that a plurality of MATs are accessed at the same time. In this case, a parameter of voltage or time required for the operation may be optimized for any one of MATs or set to an average value of a plurality of MATs.

What is claimed is:

1. A nonvolatile memory device, comprising:
a memory cell array including first and second mutually crossing lines and electrically erasable programmable memory cells arranged at intersections of said first and second lines, each memory cell containing a variable resistive element nonvolatilely storing a resistance of the variable resistive element as data;
a line selector circuit operative to decode an address signal to select said first and second lines; and
a control circuit operative to execute control on at least one of data erase, write and read for the memory cell connected between said first and second lines selected by said line selector circuit, wherein
said control circuit executes control based on one parameter selected among a plurality of parameters,
said line selector circuit specifies said parameter based on a first address portion in said address signal and selects said first and second lines based on a second address portion in said address signal.

2. The nonvolatile memory device according to claim 1, further comprising a memory block including a plurality of memory layers stacked, each memory layer containing said memory cell array formed therein,
wherein said line selector circuit selects a memory layer whose parameter is specified based on a first address portion in said address signal, and then selects said first and second lines in said selected memory layer based on a second address portion in said address signal.

3. The nonvolatile memory device according to claim 1, wherein said control circuit selects said parameter to specify a voltage value applied to said first and second lines.

4. The nonvolatile memory device according to claim 1, wherein said control circuit selects said parameter to specify a voltage application time of a voltage applied between said first and second lines.

5. The nonvolatile memory device according to claim 1, wherein said control circuit is configured to change a value of said parameter held in said control circuit.

6. The nonvolatile memory device according to claim 1, wherein said control circuit selects said parameter to specify an output timing of a pulse for use in access to said memory cell connected between said first and second lines.

7. The nonvolatile memory device according to claim 6, further comprising a memory block including a plurality of memory layers stacked, each memory layer containing said memory cell array formed therein,
wherein said control circuit selects the output timing of said pulse based on said memory layer in which said selected memory cell is formed.

8. The nonvolatile memory device according to claim 1, wherein said control circuit detects a transition in at least part of said second address portion in said address signal to start anyone of data erasing, writing and reading for said memory cell.

9. The nonvolatile memory device according to claim 8, wherein said control circuit continuously executes any one of data erasing, writing and reading for said memory cell.

10. The nonvolatile memory device according to claim 1, wherein said first address portion and said second address portion are provided by time-dividing said one address signal into two or more.

11. The nonvolatile memory device according to claim 10, wherein said line selector circuit takes in said time-divided address signal when said line selector circuit detects a signal level transition in a clock signal given to said line selector circuit.

12. The nonvolatile memory device according to claim 10, further comprising a memory block including a plurality of memory layers stacked, each memory layer containing said memory cell array formed therein,
wherein said line selector circuit selects one of said memory layers before an input of a final portion of said time-divided address signal.

13. The nonvolatile memory device according to claim 10, further comprising a memory block including a plurality of memory layers stacked, each memory layer containing said memory cell array formed therein,
wherein said line selector circuit selects a memory layer whose parameter is specified based on a first address portion in said address signal, and then selects said first and second lines in said selected memory layer based on a second address portion in said address signal.

14. A nonvolatile memory device, comprising:
a memory cell array including first and second mutually crossing lines and electrically erasable programmable memory cells arranged at intersections of said first and second lines, each memory cell containing a variable resistive element nonvolatilely storing a resistance of the variable resistive element as data;
a line selector circuit operative to decode an address signal to select said first and second lines; and
a control circuit operative to execute control on at least one of data erase, write and read for the memory cell connected between said first and second lines selected at said line selector circuit, wherein
said line selector circuit executes selection of said first line and said second line based on said address signal time-divided into two or more.

15. The nonvolatile memory device according to claim 14, wherein said line selector circuit takes in said time-divided address signal when said line selector circuit detects a signal level transition in a clock signal given to said line selector circuit.

16. The nonvolatile memory device according to claim 14, further comprising a memory block including a plurality of memory layers stacked, each memory layer containing said memory cell array formed therein,
wherein said line selector circuit selects one of said memory layers before an input of a final portion of said time-divided address signal.

17. The nonvolatile memory device according to claim 14, further comprising a memory block including a plurality of memory layers stacked, each memory layer containing said memory cell array formed therein,
wherein said line selector circuit selects a memory layer whose parameter is specified based on a first address portion in said address signal, and then selects said first and second lines in said selected memory layer based on a second address portion in said address signal.

18. A method of controlling a nonvolatile memory device, the device comprising a memory cell array including first and second mutually crossing lines and electrically erasable programmable memory cells arranged at intersections of said first and second lines, each memory cell containing a variable resistive element nonvolatilely storing a resistance of the variable resistive element as data, a line selector circuit operative to decode an address signal to select said first and second lines, and a control circuit operative to execute control on at least one of data erase, write and read for a memory cell connected between said first and second lines selected at said line selector circuit, the method comprising:
specifying said parameter based on a first address portion in said address signal at said line selector circuit;
selecting said first and second lines based on a second address portion in said address signal at said line selector circuit; and
executing control at said control circuit based on one parameter specified among a plurality of parameters at said line selector circuit.

19. The method of controlling a nonvolatile memory device according to claim 18, wherein said nonvolatile memory device further comprises a memory block including a plurality of memory layers stacked, each memory layer containing said memory cell array formed therein, the method further comprising:
selecting at said line selector circuit a memory layer whose parameter is specified based on a first address portion in said address signal; and
selecting at said line selector circuit said first and second lines in said selected memory layer based on a second address portion in said address signal.

20. The method of controlling a nonvolatile memory device according to claim 18, further comprising selecting said parameter at said control circuit to specify a voltage value applied to said first and second lines.
